(19) United States
(12) Patent Application Publication
(10) Pub. No.: US 2024/0276156 A1
(43) Pub. Date: Aug. 15, 2024

(54) Microphone and Display Panel

(71) Applicant: BOE Technology Group Co., Ltd., Beijing (CN)

(72) Inventors: Yaqian JI, Beijing (CN); Lei WANG, Beijing (CN); Yonggang CAO, Beijing (CN); Qianyan LI, Beijing (CN); Yue GOU, Beijing (CN); Yanling HAN, Beijing (CN)

(21) Appl. No.: 18/023,386

(22) PCT Filed: Mar. 31, 2022
(86) PCT No.: PCT/CN2022/084566

§ 371 Date: Feb. 27, 2023

(51) Int. Cl. H04R 19/04; H01L 25/18; H10K 59/90; H10N 39/00

(52) U.S. Cl. CPC H04R 19/04; H01L 25/18; H10K 59/90; H10N 39/00

(57) ABSTRACT

The present disclosure provides a microphone and a display panel. The microphone includes a first substrate, a cavity disposed on a side of the first substrate, and multiple resonant units disposed on the first substrate and located in the cavity, a resonant unit is configured to generate a frequency response in response to a particular acoustic signal, the frequency response of the multiple resonant units at least includes a resonant frequency response segment, and resonant frequency response segments of the multiple resonant units are at least partially different.

### CROSS-REFERENCE TO RELATED APPLICATION

The present application is a U.S. National Phase Entry of International Application No. PCT/CN2022/084566 having an international filing date of Mar. 31, 2022. The entire contents of the above-identified application are hereby incorporated by reference.

### TECHNICAL FIELD

The present disclosure relates to, but is not limited to, the field of microphone technologies, and specifically relates to a microphone and a display panel.

### BACKGROUND

A microphone is a device that converts an acoustic signal into an electrical signal. The microphone may be used as a sensor for recognizing speech by being attached to a mobile phone, a home appliance, a video display device, a virtual reality device, an augmented reality device, or an artificial intelligence speaker.

A non-resonant type is adopted for a current microphone. For example, a resonant frequency of the current microphone is about 25 kHz, while a frequency at which the microphone responding to a specific acoustic signal is 10 Hz to 20 kHz, so amplitude of the current microphone is small, which makes sensitivity of the microphone not high and a pickup distance limited.

### SUMMARY

The following is a summary of subject matters described herein in detail. The summary is not intended to limit the protection scope of claims.

In one aspect, the present disclosure provides a microphone including a first substrate, a cavity disposed on a side of the first substrate, and multiple resonant units disposed on the first substrate and located in the cavity, a resonant unit is configured to generate a frequency response in response to a particular acoustic signal, the frequency response of the multiple resonant units at least includes a resonant frequency response segment, and resonant frequency response segments of the multiple resonant units are at least partially different.

In an exemplary implementation mode, an IC chip disposed on the first substrate and located in the cavity is further included, the IC chip is connected with at least one resonant unit, the IC chip includes at least one of a filter, a gain regulator, and a summation adder, and the filter is configured to eliminate a frequency response segment other than a resonant frequency response segment of the resonant unit; the regulator is configured to flatten the resonant frequency response segment of the resonant unit; the summation adder is configured to convert a resonant frequency response segment of at least one resonant unit into an output frequency.

In an exemplary implementation mode, the IC chip includes a filter and a gain regulator sequentially connected in series, a quantity of IC chips is multiple, and filters in multiple IC chips are connected with multiple resonant units in one-to-one correspondence.

In an exemplary implementation mode, a summation adder is further included, and the summation adder is connected with all gain regulators in multiple IC chips.

In an exemplary implementation mode, the IC chip includes a filter, a gain regulator, and a summation adder sequentially connected in series, a filter of at least one IC chip is connected with multiple resonant units, and the multiple resonant units share the at least one IC chip.

In an exemplary implementation mode, the resonant unit includes an acoustic channel hole and a resonant membrane, the resonant membrane and the acoustic channel hole are all disposed on the first substrate and located in the cavity, and an orthographic projection of the resonant membrane on the plane where the first substrate is located is at least partially overlapped with an orthographic projection of the acoustic channel hole on the plane where the first substrate is located.

In an exemplary implementation mode, the resonant membrane includes a fixing portion and a sensing portion connected with each other, the fixing portion is fixed to the first substrate, and an orthographic projection of the sensing portion on the plane where the first substrate is located is at least partially overlapped with the orthographic projection of the acoustic channel hole on the plane where the first substrate is located.

In an exemplary implementation mode, the resonant membrane includes a first electrode, a second electrode, and a piezoelectric thin film disposed between the first electrode and the second electrode.

In an exemplary implementation mode, thicknesses of the resonant membranes in the multiple resonant units are different; and/or, areas of orthographic projections of the resonant membranes in the multiple resonant units on the plane where the first substrate is located are different; and/or, areas of orthographic projections of acoustic channel holes in the multiple resonant units on the plane where the first substrate is located are different.

In an exemplary implementation mode, a sub-cavity body is provided between the resonant membrane and the first substrate, and the acoustic channel hole is located in the sub-cavity body.

In an exemplary implementation mode, a second substrate located on a side of the first substrate and a sidewall located between the first substrate and the second substrate are further included, and the first substrate, the second substrate, and the sidewall surround to form the cavity.

In an exemplary implementation mode, the sidewall includes a first portion, a second portion, and a connection portion disposed between the first portion and the second portion, which are stacked.

In an exemplary implementation mode, the first portion includes a first conductive layer and a second conductive layer which are stacked, the first conductive layer is located on a side of the first portion close to the first substrate, and the second conductive layer is located on a side of the first portion away from the first substrate; and the second portion includes a third conductive layer and a fourth conductive layer which are stacked, the third conductive layer is located on a side of the second portion close to the second substrate, and the fourth conductive layer is located on a side of the second portion away from the second substrate.

In an exemplary implementation mode, a surface of the first substrate on a side close to the cavity is provided with a first barrier layer, at least a portion of the first barrier layer is located in the cavity, and the first barrier layer is integrally formed with the first portion.

In an exemplary implementation mode, a surface of the second substrate on a side close to the cavity is provided with a second barrier layer, at least a portion of the second barrier layer is located in the cavity, and the second barrier layer is integrally formed with the second portion.

In another aspect, the present disclosure also provides a display panel including a display region, a non-display region, and the aforementioned microphone located in the non-display region.

Other aspects will become apparent upon reading and understanding accompanying drawings and detailed description.

### BRIEF DESCRIPTION OF DRAWINGS

The accompanying drawings are used for providing an understanding for technical solutions of the present disclosure and constitute a part of the specification, are used for explaining the technical solutions of the present disclosure together with embodiments of the present disclosure, and do not constitute a limitation on the technical solutions of the present disclosure.

FIG. 1 is a frequency response curve graph of a microphone in the related art.

FIG. 2 is a frequency response curve graph of a microphone according to an embodiment of the present disclosure.

FIG. 3 is a first system framework diagram of a microphone according to an embodiment of the present disclosure.

FIG. 4 is a frequency response curve graph of multiple resonant units in a microphone according to an embodiment of the present disclosure.

FIG. 5 is a frequency response curve graph of a microphone according to an embodiment of the present disclosure after being processed through a filter.

FIG. 6 is a frequency response curve graph of a microphone according to an embodiment of the present disclosure after being processed through a gain regulator.

FIG. 7 is a frequency response curve graph of a microphone according to an embodiment of the present disclosure after being processed by a summation adder.

FIG. 8 is a first schematic diagram of a planar structure of a microphone according to an embodiment of the present disclosure.

FIG. 9 is a second schematic diagram of a planar structure of a microphone according to an embodiment of the present disclosure.

FIG. 10 is a first cross-sectional view of a microphone according to an embodiment of the present disclosure.

FIG. 11 is a cross-sectional view of a resonant unit in a microphone according to an embodiment of the present disclosure.

FIG. 12 is a cross-sectional view of a resonant membrane in a microphone according to an embodiment of the present disclosure.

FIG. 13 is a second cross-sectional view of a microphone according to an embodiment of the present disclosure.

FIG. 14 is a third cross-sectional view of a microphone according to an embodiment of the present disclosure.

FIG. 15 is a fourth cross-sectional view of a microphone according to an embodiment of the present disclosure.

FIG. 16 is a schematic diagram of a planar structure of a display panel according to an embodiment of the present disclosure.

FIG. 17 is a cross-sectional view of a display panel according to an embodiment of the present disclosure.

FIG. 18 is a second system framework diagram of a microphone according to an embodiment of the present disclosure.

### DETAILED DESCRIPTION

To make objectives, technical solutions, and advantages of the present disclosure more clear, the embodiments of the present disclosure will be described in detail with reference to the accompanying drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be construed as being limited only to what is described in following implementation modes. The embodiments in the present disclosure and features in the embodiments may be combined randomly with each other without conflict.

In the drawings, a size of each constituent element, a thickness of a layer, or a region is exaggerated sometimes for clarity. Therefore, one mode of the present disclosure is not necessarily limited to the size, and shapes and sizes of various components in the drawings do not reflect actual scales. In addition, the drawings schematically illustrate ideal examples, and one mode of the present disclosure is not limited to shapes, numerical values, or the like shown in the drawings.

Ordinal numerals such as “first”, “second”, and “third” in the specification are set to avoid confusion of constituent elements, but not to set a limit in quantity.

In the specification, for convenience, wordings indicating orientations or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, it may be a fixed connection, a detachable connection, or an integrated connection; may be a mechanical connection or an electrical connection; may be a direct mutual connection, or an indirect connection through middleware, or communication inside two elements. Those of ordinary skill in the art may understand specific meanings of these terms in the present disclosure according to specific situations.

In the specification, a transistor refers to an element which includes at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, a first electrode may be a source electrode, and a second electrode may be a drain electrode. In a case that transistors with opposite polarities are used or a case that a direction of a current is changed during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switching elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is defined not so strictly and numerical values within process and measurement error ranges are allowed.

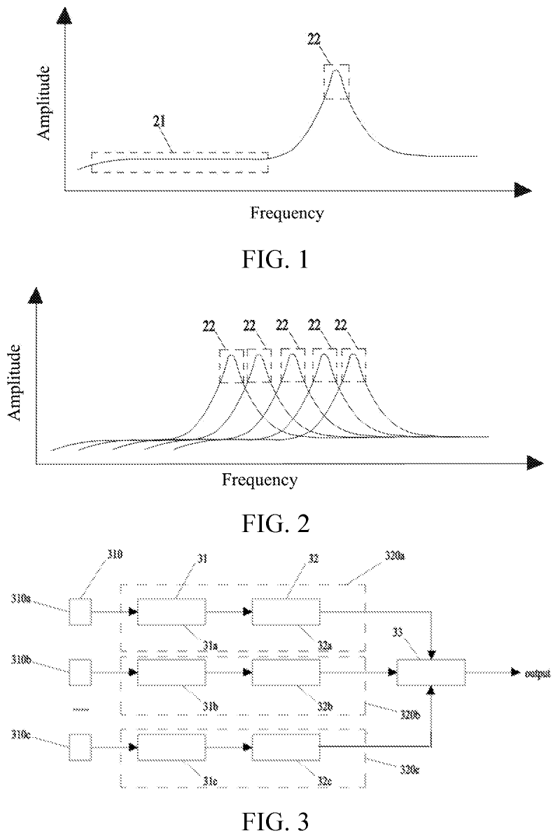

FIG. 1 is a frequency response curve graph of a microphone in the related art. FIG. 1 shows a frequency response curve graph of a microphone in the related art under 1 Pa sound pressure. As shown in FIG. 1, a non-resonant microphone may be adopted for the microphone in the related art. The microphone in the related art responds to a specific acoustic signal and generates a frequency response. The frequency response includes a non-resonant frequency response segment 21 and does not include a resonant frequency response segment 22. Since amplitude of the non-resonant frequency response segment 21 is small, sensitivity of the microphone in the related art is not high and a pickup distance is limited. Among them, the resonant frequency response segment 22 is a frequency range having a frequency corresponding to a point of strongest resonant, and amplitude of the resonant frequency response segment 22 is large. The non-resonant frequency response segment 21 is a frequency range having a frequency corresponding to gentle vibration, and amplitude of the non-resonant frequency response segment 21 is small.

FIG. 2 is a frequency response curve graph of a microphone according to an embodiment of the present disclosure. In an exemplary implementation mode, the microphone according to the embodiment of the present disclosure is configured to convert an acoustic signal into an electrical signal. The microphone according to the embodiment of the present disclosure includes multiple resonant units, a resonant unit is configured to generate a frequency response in response to a particular acoustic signal, frequency response of the multiple resonant units at least include a resonant frequency response segment 22, and resonant frequency response segments 22 of the multiple resonant units are at least partially different. For example, the microphone may include five resonant units, frequency response of each of the five resonant units includes a resonant frequency response segment 22, and resonant frequency response segments 22 of the five resonant units are all different, as shown in FIG. 2. Among them, the resonant frequency response segment 22 is a frequency range having a frequency corresponding to a point of strongest resonant, and amplitude of the resonant frequency response segment 22 is large, sensitivity of the microphone is high, and a pickup distance is long.

A frequency response generated by the microphone according to the embodiment of the present disclosure is a resonant frequency response, which includes a resonant frequency response segment 22, wherein the resonant frequency response segment 22 is a frequency range having a frequency corresponding to a point of strongest resonant, amplitude is large, sensitivity of the microphone is high, and a pickup distance is long. In the embodiment of the present disclosure, the microphone generates different resonant frequency response segments 22 through multiple resonant units, so that the sensitivity of the microphone is a weighted superposition of sensitivities of multiple different resonant frequency response segments 22, thereby improving the sensitivity of the microphone and increasing the pickup distance of the microphone. The microphone according to the embodiment of the present disclosure may be used in scenes requiring long-distance pickup such as large conference rooms and honking snapshot.

In an exemplary implementation mode, the microphone according to the embodiment of the present disclosure may be disposed in a mobile phone, a home appliance, a video display device, a virtual reality device, an augmented reality device, an artificial intelligence speaker, or the like as a sensor for recognizing speech.

The microphone according to the embodiment of the present disclosure includes multiple resonant units 310 and at least one Integrated Circuit (IC) chip 320, and the multiple resonant units 310 are connected with at least one IC chip 320. The IC chip 320 includes at least one of a filter 31, a gain regulator 32, and a summation adder 33.

FIG. 3 is a first system framework diagram of a microphone according to an embodiment of the present disclosure. In an exemplary implementation mode, as shown in FIG. 3, an IC Chip 320 includes a filter 31 and a gain regulator 32 sequentially connected in series. Output terminals of multiple resonant units 310 are connected with input terminals of filters 31 of multiple IC chips 320 in one-to-one correspondence. The microphone further includes a summation adder 33, gain regulators 32 of the multiple IC chips 320 are respectively connected with the summation adder 33.

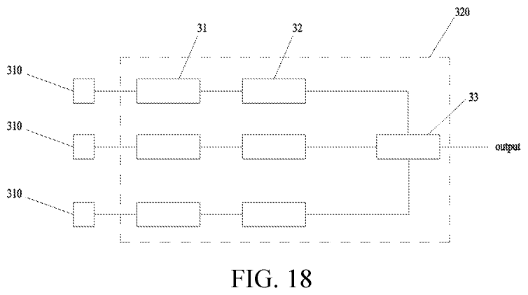

FIG. 18 is a second system framework diagram of a microphone according to an embodiment of the present disclosure. In an exemplary implementation mode, as shown in FIG. 18, an IC Chip 320 may include multiple filters 31, multiple gain regulators 32, and at least one summation adder 33, multiple resonant units 310 may be connected with the at least one IC Chip 320, the multiple resonant units 310 share the at least one IC Chip 320. For example, multiple resonant units 310 share one IC chip 320, the IC Chip 320 includes multiple filters 31, multiple gain regulators 32, and a summation adder 33. Multiple resonant units 310 may be connected with multiple filters 31 in one IC chip 320 in one-to-one correspondence. Multiple filters 31 in the IC chip 320 are connected with multiple gain regulators 32 in the IC chip 320 in one-to-one correspondence. Multiple gain regulators 32 in the IC chip 320 are connected with one summation adder 33 in the IC chip 320, and the multiple gain regulators 32 in the IC chip 320 share one summation adder 33.

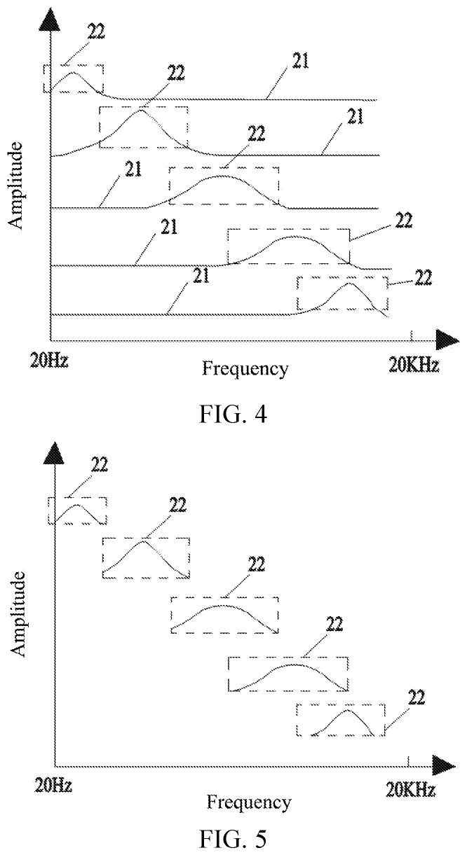

FIG. 4 is a frequency response curve graph of multiple resonant units in a microphone according to an embodiment of the present disclosure. FIG. 5 is a frequency response curve graph of a microphone according to an embodiment of the present disclosure after being processed through a filter. In an exemplary implementation mode, an acoustic signal from the outside is a broadband signal, and after acting on the microphone, multiple resonant units 310 in the microphone all respond, generating a frequency response. A filter 31 is configured to eliminate a frequency response segment other than a resonant frequency response segment 22 of a resonant unit 310. After the frequency response generated by the resonant unit 310 is processed by the filter 31, only the resonant frequency response segment 22 is retained. For example, frequency responses of the multiple resonant units 310 in the microphone each include a non-resonant frequency response segment 21 and a resonant frequency response segment 22, as shown in FIG. 4. After non-resonant frequency response segments 21 and resonant frequency response segments 22 of the multiple resonant units 310 are processed by the filter 31, the filter 31 eliminates the non-resonant frequency response segments 21 of the resonant units 310, retaining only the resonant frequency response segments 22, as shown in FIG. 5.

In an exemplary implementation mode, as shown in FIG. 3, the microphone includes a first resonant unit 310a, a second resonant unit 310b, and a third resonant unit 310c, and the first resonant unit 310a, the second resonant unit 310b, and the third resonant unit 310c all generate different resonant frequency response segments. And a resonant frequency response segment of the first resonant unit 310a is smaller than a resonant frequency response segment of the second resonant unit 310b, and the resonant frequency response segment of the second resonant unit 310b is smaller than a resonant frequency response segment of the third resonant unit 310c. The filter 31 may include a low-pass filter 31a, a band-pass filter 31b, and a high-pass filter 31c. The IC chip includes a first IC chip 320a including the low-pass filter 31a, a second IC chip 320b including the band-pass filter 31b, and a third IC chip 320c including the high-pass filter 31c. An output terminal of the first resonant unit 310a is connected with an input terminal of the low-pass filter 31a of the first IC chip 320a, an output terminal of the second resonant unit 310b is connected with an input terminal of the band-pass filter 31b of the second IC chip 320b, and an output terminal of the third resonant unit 310c is connected with an input terminal of the high-pass filter 31c of the third IC chip 320c. The low-pass filter 31a is configured to eliminate a frequency response segment other than a resonant frequency response segment 22 of the first resonant unit 310a, retaining only the resonant frequency response segment 22 of the first resonant unit 310a; the band-pass filter 31b is configured to eliminate a frequency response segment other than a resonant frequency response segment 22 of the second resonant unit 310b, retaining only the resonant frequency response segment 22 of the second resonant unit 310b; and the high-pass filter 31c is configured to eliminate a frequency response segment other than a resonant frequency response segment 22 of the third resonant unit 310c, retaining only the resonant frequency response segment 22 of the third resonant unit 310c.

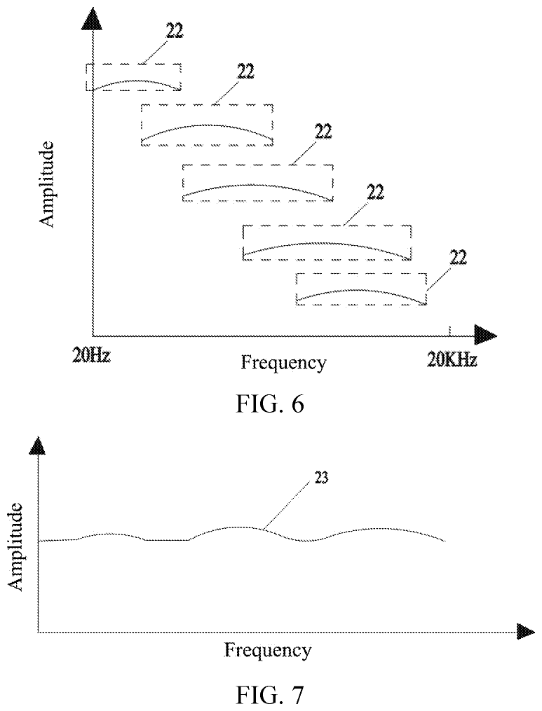

FIG. 6 is a frequency response curve graph of a microphone according to an embodiment of the present disclosure after being processed through a gain regulator. In an exemplary implementation mode, as shown in FIG. 6, a gain regulator 32 is configured to flatten a frequency response of a resonant unit 310 in the microphone, for example, the gain regulator 32 is configured to flatten a resonant frequency response segment 22 of the resonant unit 310. A gain value of the gain regulator 32 is a preset fixed value.

In an exemplary implementation mode, as shown in FIG. 3, the gain regulator 32 includes a first gain regulator 32a, a second gain regulator 32b, and a third gain regulator 32c. The first IC chip 320a further includes a first gain regulator 32a, the second IC chip 320b further includes a second gain regulator 32b, and the third IC chip 320c further includes a third gain regulator 32c. An output terminal of the low-pass filter 31a of the first IC chip 320a is connected with an input terminal of the first gain regulator 32a of the first IC chip 320a, an output terminal of the band-pass filter 31b of the second IC chip 320b is connected with an input terminal of the second gain regulator 32b of the second IC chip 320b, and an output terminal of the high-pass filter 31c of the third IC chip 320c is connected with an input terminal of the third gain regulator 32c of the third IC chip 320c. The first gain regulator 32a is configured to flatten a resonant frequency response segment 22 after being processed by the low-pass filter 31a, the second gain regulator 32b is configured to flatten a resonant frequency response segment 22 after being processed by the band-pass filter 31a, and the third gain regulator 32c is configured to flatten a resonant frequency response segment 22 after being processed by the high-pass filter 31c.

FIG. 7 is a frequency response curve graph of a microphone according to an embodiment of the present disclosure after being processed through a summation adder. In an exemplary implementation mode, as shown in FIG. 7, a summation adder 33 is configured to superimpose frequency responses of at least one resonant unit 310 on each other to obtain a final output frequency 23. For example, the summation adder 33 is configured to superimpose different resonant frequency response segments 22 of multiple resonant units 310 on each other to obtain a final output frequency 23.

In an exemplary implementation mode, as shown in FIG. 3, the microphone further includes a summation adder 33, an output terminal of the first gain regulator 32a, an output terminal of the second gain regulator 32b, and an output terminal of the third gain regulator 32c are all connected with an input terminal of the summation adder 33. The first gain regulator 32a, the second gain regulator 32b, and the third gain regulator 32c share one summation adder 33. The summation adder 33 is configured to superimpose a resonant frequency response segment 22 processed by the first gain regulator 32a, a resonant frequency response segment 22 processed by the second gain regulator 32b, and a resonant frequency response segment 22 processed by the third gain regulator 32c on each other to obtain a final output frequency 23.

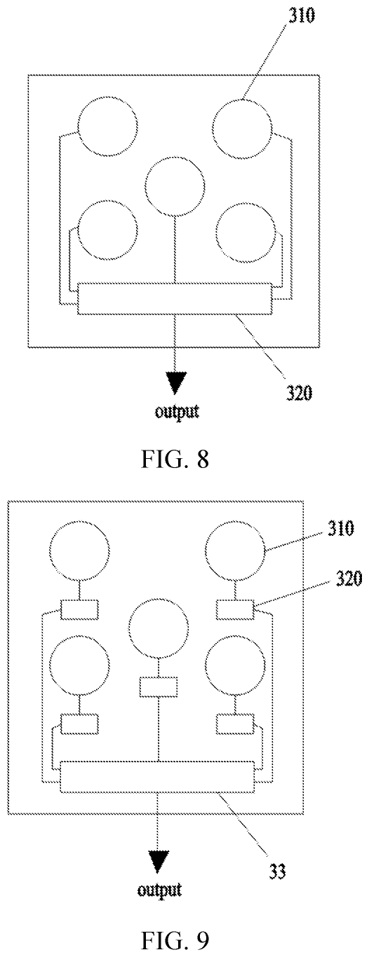

FIG. 8 is a first schematic diagram of a planar structure of a microphone according to an embodiment of the present disclosure. In an exemplary implementation mode, the microphone according to the embodiment of the present disclosure includes multiple resonant units 310 and at least one IC chip 320. The multiple resonant units 310 are arranged in an array, the multiple resonant units 310 are all connected with the at least one IC chip 320, and the multiple resonant units 310 share the at least one IC chip 320. For example, multiple resonant units 310 are all connected with one IC chip 320, and the multiple resonant units 310 share the one IC chip 320. The IC chip 320 may include multiple filters 31, multiple gain regulators 32, and at least one summation adder 33, and the multiple filters 31, the multiple gain regulators 32, and the at least one summation adder 33 are integrated in one IC chip 320, as shown in FIG. 8. According to the microphone of the embodiment of the present disclosure, multiple resonant units 310 share at least one IC chip 320, a quantity of IC chips 320 is reduced, a cost is reduced, and a pitch between multiple resonant units 310 is reduced, so that a structure of the microphone is compact, and a size of the microphone is reduced.

In an exemplary implementation mode, the multiple resonant units 310 may include array arrangements of various shapes. For example, the multiple resonant units 310 may include a regular or irregular-shaped array arrangement such as a rectangular array arrangement, a triangular array arrangement, a circular array arrangement, a diamond array arrangement, an elliptical array arrangement, and a polygonal array arrangement.

In an exemplary implementation mode, a shape of an orthographic projection of the resonant unit 310 on a plane where the microphone is located may include a regular or irregular shape such as a rectangle, a triangle, a circle, a diamond, an ellipse, and a polygon. For example, the shape of the orthographic projection of the resonant unit 310 on the plane where the microphone is located is a circle.

FIG. 9 is a second schematic diagram of a planar structure of a microphone according to an embodiment of the present disclosure. In an exemplary implementation mode, as shown in FIG. 9, the microphone according to the embodiment of the present disclosure includes multiple resonant units 310 arranged in an array and multiple IC chips 320, wherein the multiple resonant units 310 are connected one-to-one with the multiple IC chips 320, i.e., one resonant unit 310 is connected with one IC chip 320. The IC chip 320 may include a filter 31 and a gain regulator 32 connected in series. An output terminal of the resonant unit 310 is connected with an input terminal of a filter 31 in a corresponding IC chip, and an output terminal of the filter 31 in the IC chip is connected with an input terminal of a gain regulator 32 in the IC chip.

In an exemplary implementation mode, as shown in FIG. 9, the microphone according to the embodiment of the present disclosure further includes at least one summation adder 33, gain regulators 32 in the multiple IC chips 320 are connected with at least one summation adder 33. The multiple IC chips 320 may share at least one summation adder 33. For example, the gain regulators 32 in the multiple IC chips 320 may be connected with one summation adder 33, and the multiple IC chips 320 may share one summation adder 33.

A frequency response of a resonant unit 310 in the microphone according to the embodiment of the present disclosure is processed by a filter 31, a gain regulator 32, and a summation and adder 33 to obtain an output frequency, and a noise resistance capability is strong.

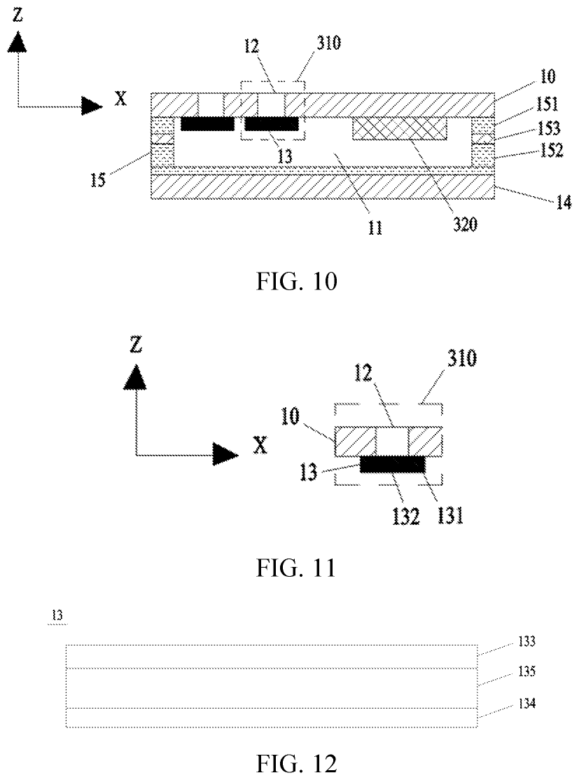

FIG. 10 is a first cross-sectional view of a microphone according to an embodiment of the present disclosure. In an exemplary implementation mode, as shown in FIG. 10, the microphone according to the embodiment of the present disclosure includes a first substrate 10, a cavity 11 disposed on a side of the first substrate 10, and multiple resonant units 310 disposed on the first substrate 10 and located in the cavity 11. The cavity 11 is configured to accommodate multiple resonant units 310 and provide a resonant space to the multiple resonant units 310. A resonant unit 310 is configured to generate a frequency response in response to an acoustic signal from the outside. The frequency response of the multiple resonant units 310 includes at least a resonant frequency response segment, and resonant frequency response segments of the multiple resonant units are at least partially different. The resonant unit 310 includes an acoustic channel hole 12 and a resonant membrane 13. The resonant membrane 13 is configured to generate a frequency response in response to an acoustic signal from the outside. The resonant membrane 13 is disposed on a surface of the first substrate 10 on a side close to the cavity 11 and is located in the cavity 11. An orthographic projection of the resonant membrane 13 on a plane where the first substrate 10 is located is at least partially overlapped with an orthographic projection of the acoustic channel hole 12 on the plane where the first substrate is located. For example, the resonant membrane 13 covers the acoustic channel hole 12. The acoustic channel hole 12 is configured to provide a channel for inputting of an acoustic signal to the resonant membrane 13, and the acoustic signal from the outside acts on the resonant membrane 13 through the acoustic channel hole 12, so that the resonant membrane 13 generates a frequency response. The acoustic channel hole 12 is disposed on the first substrate 10 and located in the cavity 11, and penetrates through the first substrate 10 in a thickness direction of the first substrate 10.

FIG. 11 is a cross-sectional view of a resonant unit in a microphone according to an embodiment of the present disclosure. In an exemplary implementation mode, as shown in FIG. 11, a resonant membrane 13 includes a fixing portion 131 and a sensing portion 132 connected with each other. The fixing portion 131 is located at both ends of the resonant membrane 13 in a first direction X, and the fixing portion 131 may extend along the first direction X. An orthographic projection of the fixing portion 131 on the plane where the first substrate 10 is located is not overlapped with an orthographic projection of the acoustic channel hole 12 on the plane where the first substrate 10 is located. A surface of the fixing portion 131 on a side close to the first substrate 10 is in contact with the first substrate 10, the fixing portion 131 is fixed to the first substrate 10, and the resonant membrane 13 is fixed on the first substrate 10 through the fixing portion 131. The sensing portion 132 is located between two fixing portions 131 in the first direction X, and the sensing portion 132 may extend along the first direction X. An orthographic projection of the sensing portion 132 on the plane where the first substrate 10 is located is at least partially overlapped with the orthographic projection of the acoustic channel hole 12 on the plane where the first substrate 10 is located. The sensing portion 132 is configured to generate a frequency response in response to an acoustic signal from the outside, and the frequency response generated by the sensing portion 132 includes at least a resonant frequency response segment, so that sensitivity of the microphone to receive an acoustic signal can be improved.

In an exemplary implementation mode, as shown in FIG. 10, resonant membranes 13 in multiple resonant units 310 may be arranged coplanar in the cavity 12 without overlapping. The first substrate 10 may be shared by multiple resonant membranes 13 in the cavity 12, i.e. the first substrate 10 is provided with the multiple resonant membranes 13, and orthographic projections of the multiple resonant membranes 13 on the plane where the first substrate 10 is located are not overlapped.

In an exemplary implementation mode, the first substrate 10 may be made of a glass material or a silicon-based material. For example, the first substrate 10 is made of a silicon-based material, a resonant membrane 13 is transferred on the first substrate 10, and the resonant membrane 13 may be made of a capacitive resonant membrane or a piezoelectric resonant membrane. In some embodiments, a first substrate may also be made of another material, for example, the first substrate may be made of a metal or a polymer resin or the like.

FIG. 12 is a cross-sectional view of a resonant membrane in a microphone according to an embodiment of the present disclosure. In an exemplary implementation mode, as shown in FIG. 12, a resonant membrane 13 includes a first electrode 133, a second electrode 134, and a piezoelectric thin film 135 disposed between the first electrode 133 and the second electrode 134, and the piezoelectric thin film 135 is configured to generate a frequency response in response to an acoustic signal from the outside. The first electrode 133 and the second electrode 134 are configured to convert the frequency response of the piezoelectric thin film 135 into an electrical signal.

In an exemplary implementation mode, multiple resonant units 310 in the microphone according to the embodiment of the present disclosure generate different resonant frequency response segments. For the microphone according to the embodiment of the present disclosure, a size of a resonant unit 310 may be changed to adjust a resonant frequency response segment of the resonant unit 310, for example, the resonant frequency response segment of the resonant unit 310 is adjusted by changing a thickness of the resonant membrane 13; or, the resonant frequency response segment of the resonant unit 310 is adjusted by changing an area of an orthographic projection of the resonant membrane 13 on the plane where the first substrate 10 is located; or, the resonant frequency response segment of the resonant unit 310 is adjusted by changing an area of an orthographic projection of the acoustic channel hole 12 on the plane where the first substrate 10 is located.

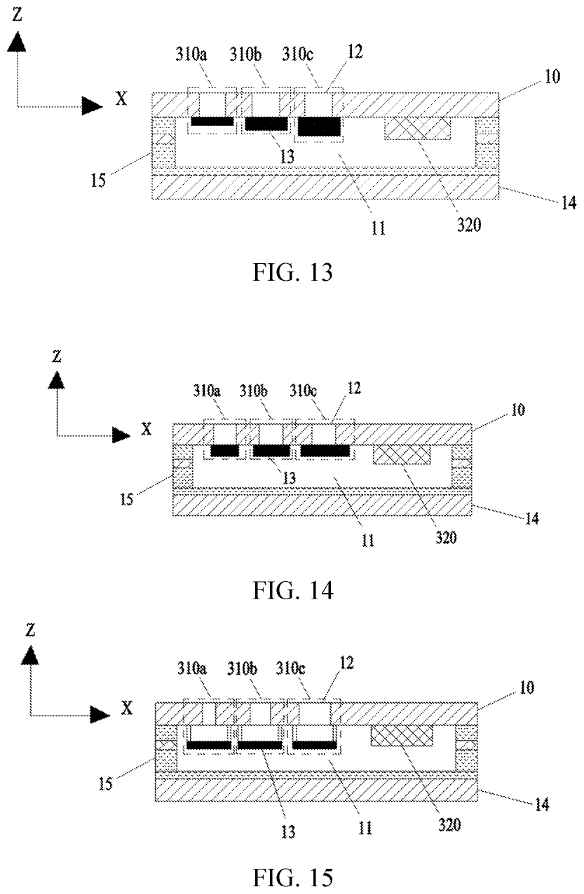

FIG. 13 is a second cross-sectional view of a microphone according to an embodiment of the present disclosure. In an exemplary implementation mode, as shown in FIG. 13, the microphone according to the embodiment of the present disclosure includes a first resonant unit 310a, a second resonant unit 310b, and a third resonant unit 310c. An area of an orthographic projection of a resonant membrane 13 in the first resonant unit 310a on the plane where the first substrate 10 is located, an area of an orthographic projection of a resonant membrane 13 in the second resonant unit 310b on the plane where the first substrate 10 is located, and an area of an orthographic projection of a resonant membrane 13 in the third resonant unit 310c on the plane where the first substrate 10 is located are the same. An area of an orthographic projection of an acoustic channel hole 12 in the first resonant unit 310a on the plane where the first substrate 10 is located, an area of an orthographic projection of an acoustic channel hole 12 in the second resonant unit 310b on the plane where the first substrate 10 is located, and an area of an orthographic projection of an acoustic channel hole 12 in the third resonant unit 310c on the plane where the first substrate 10 is located are the same. A thickness of the resonant membrane 13 in the first resonant unit 310a is smaller than a thickness of the resonant membrane 13 in the second resonant unit 310b, and the thickness of the resonant membrane 13 in the second resonant unit 310b is smaller than a thickness of the resonant membrane 13 in the third resonant unit 310c, so that a resonant frequency response segment of the first resonant unit 310a is smaller than a resonant frequency response segment of the second resonant unit 310b, and the resonant frequency response segment of the second resonant unit 310b is smaller than a resonant frequency response segment of the third resonant unit 310c.

FIG. 14 is a third cross-sectional view of a microphone according to an embodiment of the present disclosure. In an exemplary implementation mode, as shown in FIG. 14, the microphone according to the embodiment of the present disclosure includes a first resonant unit 310a, a second resonant unit 310b, and a third resonant unit 310c, a thickness of a resonant membrane 13 in the first resonant unit 310a, a thickness of a resonant membrane 13 in the second resonant unit 310b, and a thickness of a resonant membrane 13 in the third resonant unit 310c are the same. An area of an orthographic projection of an acoustic channel hole 12 in the first resonant unit 310a on the plane where the first substrate 10 is located, an area of an orthographic projection of an acoustic channel hole 12 in the second resonant unit 310b, and an area of an orthographic projection of an acoustic channel hole 12 in the third resonant unit 310c on the plane where the first substrate 10 is located are the same. An area of an orthographic projection of the resonant membrane 13 in the first resonant unit 310a on the plane where the first substrate 10 is located is smaller than an area of an orthographic projection of the resonant membrane 13 in the second resonant unit 310b on the plane where the first substrate 10 is located, and the area of the orthographic projection of the resonant membrane 13 in the second resonant unit 310b on the plane where the first substrate 10 is located is smaller than an area of an orthographic projection of the resonant membrane 13 in the third resonant unit 310c on the plane where the first substrate 10 is located, so that a resonant frequency response segment of the first resonant unit 310a is larger than a resonant frequency response segment of the second resonant unit 310b, and the resonant frequency response segment of the second resonant unit 310b is larger than a resonant frequency response segment of the third resonant unit 310c.

FIG. 15 is a fourth cross-sectional view of a microphone according to an embodiment of the present disclosure. In an exemplary implementation mode, as shown in FIG. 15, the microphone according to the embodiment of the present disclosure includes a first resonant unit 310a, a second resonant unit 310b, and a third resonant unit 310c. A first sub-cavity body is provided between a resonant membrane 13 in the first resonant unit 310a and the first substrate 10, and an acoustic channel hole 12 in the first resonant unit 310a is located in the first sub-cavity body. A second sub-cavity body is provided between a resonant membrane 13 in the second resonant unit 310b and the first substrate 10, and an acoustic channel hole 12 in the second resonant unit 310b is located in the second sub-cavity body. A third sub-cavity body is provided between a resonant membrane 13 in the third resonant unit 310c and the first substrate 10, and an acoustic channel hole 12 in the third resonant unit 310c is located in the third sub-cavity body. A thickness of the resonant membrane 13 in the first resonant unit 310a, a thickness of the resonant membrane 13 in the second resonant unit 310b, and a thickness of the resonant membrane 13 in the third resonant unit 310c are the same. An area of an orthographic projection of the resonant membrane 13 in the first resonant unit 310a on the plane where the first substrate 10 is located, an area of an orthographic projection of the resonant membrane 13 in the second resonant unit 310b on the plane where the first substrate 10 is located, and an area of an orthographic projection of the resonant membrane 13 in the third resonant unit 310c on the plane where the first substrate 10 is located are the same. An area of an orthographic projection of the acoustic channel hole 12 in the first resonant unit 310a on the plane where the first substrate 10 is located is smaller than an area of an orthographic projection of the acoustic channel hole 12 in the second resonant unit 310b on the plane where the first substrate 10 is located, and the area of the orthographic projection of the acoustic channel hole 12 in the second resonant unit 310b on the plane where the first substrate 10 is located is smaller than an area of an orthographic projection of the acoustic channel hole 123 in the third resonant unit 310c on the plane where the first substrate 10 is located. According to the principle of Helmholtz resonant cavity, a resonant frequency response segment of the first resonant unit 310a is smaller than a resonant frequency response segment of the second resonant unit 310b, and the resonant frequency response segment of the second resonant unit 310b is smaller than a resonant frequency response segment of the third resonant unit 310c.

In an exemplary implementation mode, as shown in FIG. 10, an IC chip 320 in the microphone according to the embodiment of the present disclosure is disposed on the first substrate 10 and located in the cavity 11, the IC Chip 320 and the multiple resonant units 310 are arranged coplanar without overlapping, the IC chip 320 and the multiple resonant units 310 share the first substrate 10, and an orthographic projection of the IC Chip 320 on the plane where the first substrate 10 is located is not overlapped with each of orthographic projections of the multiple resonant membranes 13 on the plane where the first substrate 10 is located.

In an exemplary implementation mode, as shown in FIG. 10, the microphone according to the embodiment of the present disclosure further includes a second substrate 14 located on a side of the first substrate 10 and a sidewall 15 located between the first substrate 10 and the second substrate 14. The sidewall 15 may extend along a second direction Z, one end of the sidewall 15 in the second direction Z is in contact with the first substrate 10, the other end of the sidewall 15 in the second direction Z is in contact with the second substrate 14. The sidewall 15 is annular, and the first substrate 10, the second substrate 14, and the sidewall 15 are combined to surround to form the cavity 11. The first substrate 10, the second substrate 14, and the sidewall 15 encapsulate the multiple resonant units 310 in the cavity 11. Among them, the first direction X is different from the second direction Z, for example, the first direction X is perpendicular to the second direction Z.

In an exemplary implementation mode, as shown in FIG. 10, the sidewall 15 includes a first portion 151, a second portion 152, and a connection portion 153 which is disposed between the first portion 151 and the second portion 152, which are stacked in the second direction Z. The first portion 151 and the second portion 152 may be made of a conductive material to block electromagnetic interference from a side portion of the microphone.

In an exemplary implementation mode, as shown in FIG. 10, the first portion 151 and the second portion 152 may be of a single-layer structure or a multi-layer structure. For example, the first portion 151 and the second portion 152 may be of a multi-layer structure. The first portion 151 may include a first conductive layer and a second conductive layer which are stacked in the second direction Z. The first conductive layer is located on a side of the first portion 151 close to the first substrate 10, and the second conductive layer is located on a side of the first portion 151 away from the first substrate 10. The first conductive layer may be made of copper, and the second conductive layer may be made of aluminum. The second portion 152 may include a third conductive layer and a fourth conductive layer stacked in the second direction Z. The third conductive layer is located on a side of the second portion 152 close to the second substrate 14, the fourth conductive layer is located on a side of the first portion 151 away from the second substrate 14, the third conductive layer may be made of copper, and the fourth conductive layer may be made of aluminum.

In an exemplary implementation mode, as shown in FIG. 10, the connection portion 153 connects the first portion 151 and the second portion 152. One end of the connection portion 153 in the second direction Z is in contact with the first portion 151, and the other end of the connection portion 153 in the second direction Z is in contact with the second portion 152. A conductive adhesive may be adopted for the connection portion 153.

In an exemplary implementation mode, a surface of the first substrate 10 on a side close to the cavity 11 is provided with a first barrier layer, and at least a portion of the first barrier layer is located in the cavity 11. The first barrier layer may be made of a conductive material to block electromagnetic interference of the microphone from a side of the first substrate 10. Among them, the first barrier layer and the first portion 151 of the sidewall 15 may be integrally formed, and made of a same material through a same preparation process.

In an exemplary implementation mode, a surface of the second substrate 14 on a side close to the cavity 11 is provided with a second barrier layer, and at least a portion of the second barrier layer is located in the cavity 11. The second barrier layer may be made of a conductive material to block electromagnetic interference of the microphone from a side of the second substrate 14. Among them, the second barrier layer and the second portion 152 of the sidewall 15 may be integrally formed, and made of a same material through a same preparation process.

FIG. 16 is a schematic diagram of a planar structure of a display panel according to an embodiment of the present disclosure. In an exemplary implementation mode, as shown in FIG. 16, an embodiment of the present disclosure provides a display panel that includes a microphone 300 as described above. The display panel according to the embodiment of the present disclosure may include a display region 100 and a non-display region 200. The display region 100 is used for displaying an image. The display region 100 includes a base substrate and multiple sub-pixels PX arranged regularly on the base substrate, and a sub-pixel is used for emitting light. For example, the display region 100 includes multiple first sub-pixels PX, multiple second sub-pixels PX, and multiple third sub-pixels PX which are arranged regularly, a first sub-pixel PX may be a red (R) sub-pixel, a second sub-pixel PX may be a green (G) sub-pixel, and a third sub-pixel PX may be a blue (B) sub-pixel. The display panel may provide an image through multiple sub-pixels PX in the display region 100. An image is not displayed in the non-display region 200 and the non-display region 200 may completely or partially surround the display region 100. Multiple microphones 300 described above are located in a non-display region 200 to form a microphone array. For example, the non-display region 200 is disposed around the display region 100, the non-display region 200 includes a first edge portion region and a second edge portion region, which are respectively located on opposite sides of the display region 100 in a first direction X. Microphone arrays are provided in both the first edge portion region and the second edge portion region, and the microphone arrays extend along a third direction Y. Among them, the third direction Y is different from each of the first direction X and the second direction Z, for example, the third direction Y is perpendicular to each of the first direction X and the second direction Z.

In an exemplary implementation mode, as shown in FIG. 16, the display panel includes a display region 100 having a rectangular shape. In some embodiments, the display region 100 may also have a circular shape, an elliptical shape, or a polygonal shape such as a triangle and a pentagon.

In an exemplary implementation mode, the display panel may be pad display panel. In some embodiments, other types of display panels may also be adopted for the display panel, for example, a flexible display panel, a foldable display panel, a rollable display panel, and the like.

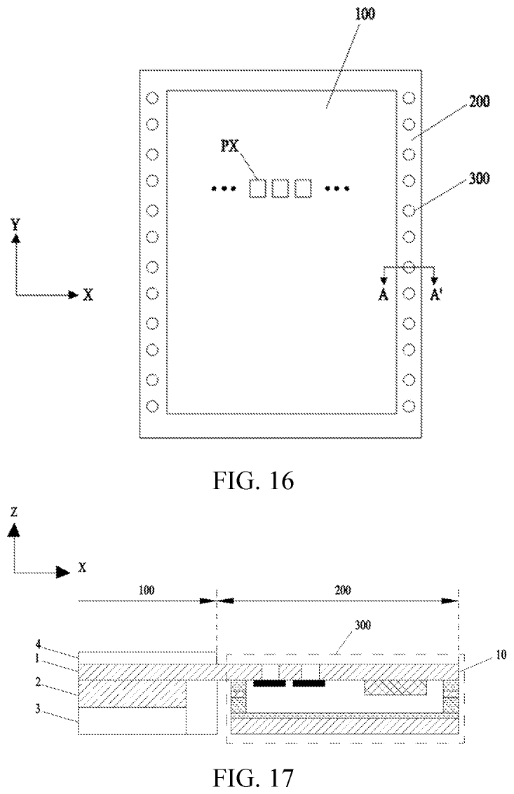

FIG. 17 is a cross-sectional view of a display panel according to an embodiment of the present disclosure. FIG. 17 is a cross-sectional view taken along an A-A′ direction in FIG. 16. In an exemplary implementation mode, as shown in FIG. 17, a display region 100 of the display panel according to the embodiment of the present disclosure includes a base substrate 1, a light emitting structure layer 2 disposed on the base substrate 1, an encapsulation layer 3 disposed on a side of the light emitting structure layer 2 away from the base substrate 1, and a polarizer 4 disposed on a side of the base substrate 1 away from the light emitting structure layer 2. The light emitting structure layer 2 is configured to emit display light, so that an image is displayed in the display region 100. The light emitting structure layer 2 includes multiple light emitting devices. A light emitting device may be an Organic Light Emitting Diode (OLED) light emitting device. The encapsulation layer 3 covers the multiple light emitting devices for protecting the light emitting devices and preventing moisture or oxygen from the outside from damaging the light emitting devices.

In an exemplary implementation mode, the base substrate 1 may include glass, a metal, or a polymer resin. When the base substrate 1 is a flexible or bendable base substrate, the base substrate 1 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The base substrate 1 may also have a multilayer structure, and the multilayer structure includes two layers each containing such a polymer resin and a barrier layer containing an inorganic material (e.g., silicon oxide, silicon nitride, or silicon oxynitride) between the two layers.

In an exemplary implementation mode, the encapsulation layer 3 may include a first inorganic encapsulation layer, a second inorganic encapsulation layer, and an organic encapsulation layer disposed between the first inorganic encapsulation layer and the second inorganic encapsulation layer. The first inorganic encapsulation layer and the second inorganic encapsulation layer may each include one or more inorganic insulation materials. An inorganic insulation material may include one of aluminum oxide, titanium oxide, tantalum oxide, hafnium oxide, zinc oxide, silicon oxide, silicon nitride and/or silicon oxynitride. The first inorganic encapsulation layer and the second inorganic encapsulation layer may be formed through chemical vapor deposition. The organic encapsulation layer may include a polymer-based material. The polymer-based material may include one of acrylic resin, epoxy resin, polyimide, and polyethylene.

In the exemplary implementation mode, a specific structure of the microphone 300 in the display panel according to the embodiment of the present disclosure has been described above, and the embodiment of the present disclosure will not be repeated here. Among them, the first substrate 10 of the microphone 300 and the base substrate 1 of the display region 100 are integrally formed, and the first substrate 10 of the microphone 300 and the base substrate 1 of the display region 100 are prepared through a same preparation process using a same material, that is, the microphone 300 and the display region 100 may share the base substrate 1.

In some embodiments, the aforementioned microphone may also be located in the display region of the display panel, and there is no overlapping region between an orthographic projection of the microphone on the base substrate of the display region and an orthographic projection of a sub-pixel PX on the base substrate of the display region, so as to prevent the microphone from blocking light emitted by the sub-pixel PX and affecting a display effect.

The present disclosure also provides a display apparatus including the display panel of the aforementioned exemplary embodiments. The display apparatus may be any product or component with a display function, such as a mobile phone, a tablet computer, a television, a display, a laptop computer, a digital photo frame, or a navigator.

Although implementation modes disclosed in the present disclosure are described as above, the described contents are only implementation modes which are used for convenience of understanding of the present disclosure, but are not intended to limit the present disclosure. Any skilled person in the art to which the present disclosure pertains may make any modification and variation in forms and details of implementation without departing from the spirit and scope of the present disclosure. However, the scope of patent protection of the present disclosure should be subject to the scope defined in the appended claims.

1. A microphone, comprising a first substrate, a cavity disposed on a side of the first substrate, and multiple resonant units disposed on the first substrate and located in the cavity, a resonant unit is configured to generate a frequency response in response to a particular acoustic signal, the frequency response of the multiple resonant units at least comprises a resonant frequency response segment, and resonant frequency response segments of the multiple resonant units are at least partially different.

2. The microphone according to claim 1, further comprising an IC chip disposed on the first substrate and located in the cavity, the IC chip is connected with at least one resonant unit, the IC chip comprises at least one of a filter, a gain regulator, and a summation adder, and the filter is configured to eliminate a frequency response segment other than a resonant frequency response segment of the resonant unit; the regulator is configured to flatten the resonant frequency response segment of the resonant unit; the summation adder is configured to convert a resonant frequency response segment of at least one resonant unit into an output frequency.

3. The microphone according to claim 2, wherein the IC chip comprises a filter and a gain regulator sequentially connected in series, a quantity of IC chips is multiple, and filters in multiple IC chips are connected with multiple resonant units in one-to-one correspondence.

4. The microphone according to claim 3, further comprising a summation adder, and the summation adder is connected with all gain regulators in the multiple IC chips.

5. The microphone according to claim 2, wherein the IC chip comprises a filter, a gain regulator, and a summation adder sequentially connected in series, a filter of at least one IC chip is connected with the multiple resonant units, and the multiple resonant units share the at least one IC chip.

6. The microphone according to claim 1, wherein the resonant unit comprises an acoustic channel hole and a resonant membrane, the resonant membrane and the acoustic channel hole are all disposed on the first substrate and located in the cavity, and an orthographic projection of the resonant membrane on the plane where the first substrate is located is at least partially overlapped with an orthographic projection of the acoustic channel hole on the plane where the first substrate is located.

7. The microphone according to claim 6, wherein the resonant membrane comprises a fixing portion and a sensing portion connected with each other, the fixing portion is fixed to the first substrate, and an orthographic projection of the sensing portion on the plane where the first substrate is located is at least partially overlapped with the orthographic projection of the acoustic channel hole on the plane where the first substrate is located.

8. The microphone according to claim 6, wherein the resonant membrane comprises a first electrode, a second electrode, and a piezoelectric thin film disposed between the first electrode and the second electrode.

9. The microphone according to claim 6, wherein thicknesses of resonant membranes in the multiple resonant units are different; and/or, areas of orthographic projections of the resonant membranes in the multiple resonant units on the plane where the first substrate is located are different; and/or, areas of orthographic projections of acoustic channel holes in the multiple resonant units on the plane where the first substrate is located are different.

10. The microphone according to claim 6, wherein a sub-cavity body is provided between the resonant membrane and the first substrate, and the acoustic channel hole is located in the sub-cavity body.

11. The microphone according to claim 1, further comprising a second substrate located on a side of the first substrate and a sidewall located between the first substrate and the second substrate, and the first substrate, the second substrate, and the sidewall surround to form the cavity.

12. The microphone according to claim 11, wherein the sidewall comprises a first portion, a second portion, and a connection portion disposed between the first portion and the second portion, which are stacked.

13. The microphone according to claim 12, wherein the first portion comprises a first conductive layer and a second conductive layer which are stacked, the first conductive layer is located on a side of the first portion close to the first substrate, and the second conductive layer is located on a side of the first portion away from the first substrate; and the second portion comprises a third conductive layer and a fourth conductive layer which are stacked, the third conductive layer is located on a side of the second portion close to the second substrate, and the fourth conductive layer is located on a side of the second portion away from the second substrate.

14. The microphone according to claim 12, wherein a surface of the first substrate on a side close to the cavity is provided with a first barrier layer, at least a portion of the first barrier layer is located in the cavity, and the first barrier layer is integrally formed with the first portion.

15. The microphone according to claim 12, wherein a surface of the second substrate on a side close to the cavity is provided with a second barrier layer, at least a portion of the second barrier layer is located in the cavity, and the second barrier layer is integrally formed with the second portion.

16. A display panel, comprising a display region, a non-display region, and a microphone according to claim 1 located in the non-display region.

17. A display panel, comprising a display region, a non-display region, and a microphone according to claim 2 located in the non-display region.

18. A display panel, comprising a display region, a non-display region, and a microphone according to claim 3 located in the non-display region.

19. A display panel, comprising a display region, a non-display region, and a microphone according to claim 6 located in the non-display region.

20. A display panel, comprising a display region, a non-display region, and a microphone according to claim 11 located in the non-display region.
